(19) United States
(12) Patent Application Publication
(10) Pub. No.: US 2023/0018842 A1
(43) Pub. Date: Jan. 19, 2023

(54) WORKPIECE SUPPORT SYSTEM FOR PLASMA TREATMENT AND METHOD OF USING THE SAME

(71) Applicant: Nordson Corporation, Westlake, OH (US)

(72) Inventors: Zhao JIANGANG, Concord, CA (US); Robert S. CONDRASHOFF, Concord, CA (US); James HARROUN, Concord, CA (US); David A. PRESTON, Concord, CA (US)

(21) Appl. No.: 17/785,944

(22) PCT Filed: Jan. 7, 2021
(86) PCT No.: PCT/US2021/012471

§ 371 Date: Jun. 16, 2022

Related U.S. Application Data
(60) Provisional application No. 62/958,865, filed on Jan. 9, 2020.

(51) Int. Cl. H01J 37/32; H01L 21/673

(52) U.S. Cl. CPC H01J 37/32715; H01J 37/32568; H01L 21/6732; H01J 2237/032; H01J 2237/1825; H01J 37/32816; H01L 21/4835

(57) ABSTRACT

In one example, a workpiece support structure of a plasma treatment chamber has upper and lower ends, and first and second support members that extend between the upper and lower ends. The support members are electrically isolated from one another and offset from one another along a horizontal direction so as to define a cavity therebetween. The first and second support members support electrodes within the cavity such that (1) the electrodes are offset from one another along the vertical direction, (2) the electrodes extend between the first and second support members along the first horizontal direction, (3) a first set of the electrodes are electrically coupled to the first support member and electrically isolated from the second support member, and (4) a second set of the electrodes, different from the first set, are electrically coupled to the second support member and electrically isolated from the first support member.

### CROSS-REFERENCE TO RELATED APPLICATIONS

This application is a National Stage Application of International Patent App. No. PCT/US2021/012471, filed Jan. 7, 2021, which claims the benefit of U.S. Provisional Patent App. No. 62/958,865, filed Jan. 9, 2020, the entire disclosures of both of which are hereby incorporated by reference as if set forth in their entirety herein.

### TECHNICAL FIELD

The present disclosure relates generally to plasma processing and, in particular, to plasma treatment systems and methods for treating substrates.

### BACKGROUND

Plasma treatment is frequently used to modify the surface properties of substrates used in a diversity of applications including, but not limited to, integrated circuits, electronic packages, and printed circuit boards. In particular, plasma treatment may be used in electronics packaging, for example, to etch resin, to remove drill smear, to increase surface activation and/or surface cleanliness for eliminating delamination and bond failures, to improve wire bond strength, to ensure void free underfilling of chips attached to printed circuit boards, to remove oxides from surfaces, to enhance die attach, and to improve adhesion for chip encapsulation.

In a conventional plasma processing system, multiple substrates are placed inside a vacuum chamber, the vacuum chamber is evacuated and filled with a partial pressure of a source gas, a plasma consisting of a partially ionized source gas is generated inside the vacuum chamber, and a surface of each substrate is exposed to the plasma species. The outermost surface layer(s) of atoms are removed from each substrate by physical sputtering, chemically-assisted sputtering, and chemical reactions promoted by the plasma. The physical or chemical action may be used to condition the surface to improve properties such as adhesion, to selectively remove an extraneous surface layer, or to clean undesired contaminants from the substrate's surface.

In conventional plasma processing systems, a magazine holds a plurality of panels such that each panel is in a vertical orientation and the panels are spaced from one another along a horizontal direction. The magazine is inserted into a plasma treatment chamber having a plurality of vertical planar electrodes such that each panel is received between a pair of the vertical planar electrodes. The electrodes are energized with a suitable atmosphere present in the treatment chamber of the treatment system to generate the plasma. The environment between each planar vertical electrode and the adjacent surface of the panel supplies a local process chamber in which the partially ionized source gas is present.

Plasma processing may be used during the manufacture of semiconductor substrates. Process uniformity across the entire surface area of each substrate achieved by conventional processing systems, while adequate for their intended purpose, may be insufficient as technological advances are made.

### SUMMARY

In an example, a workpiece support system is configured to be removably received in a chamber of a plasma treatment system. The workpiece support system comprises an upper end and a lower end offset from one another along a vertical direction. The workpiece support system comprises first and second support members that extend between the upper end and lower end, that are offset from one another along a first horizontal direction such that a cavity is defined between the upper and lower ends and between the first and second support members, and that are electrically isolated from one another. The first and second support members are configured to support electrodes within the cavity such that the electrodes are offset from one another along the vertical direction, the electrodes extend between the first and second support members along the first horizontal direction, a first set of the electrodes is electrically coupled to the first support member and electrically isolated from the second support member, and a second set of the electrodes, different from the first set, is electrically coupled to the second support member and electrically isolated from the first support member.

Another example is a method of plasma treating product. The method comprises a step of inserting a workpiece support system into a chamber of a plasma treatment system. The workpiece support system has first and second support members that extend along a vertical direction, that are offset from one another along a horizontal direction, and that are electrically isolated from one another. The first and second support members support a plurality of electrodes within a cavity of the workpiece support system, where the electrodes are offset from one another along the vertical direction and extend between the first and second support members along the horizontal direction. The method comprises a step of electrically coupling a first electrical contact of the chamber to the first support member such that a first set of the electrodes is electrically coupled to the first support member and electrically isolated from the second support member. The method comprises a step of electrically coupling a second electrical contact of the chamber to the second support member such that a second set of electrodes, different from the first set, is electrically coupled to the second support member and electrically isolated from the first support member. The method comprises a step of operating the plasma treatment system by at least partially evacuating an atmosphere within the chamber, delivering a source gas between the electrodes, and supplying power to at least one of the first and second electrical contacts of the chamber to as to establish a voltage differential between the first and second support members.

### BRIEF DESCRIPTION OF THE DRAWINGS

The following description of the illustrative examples may be better understood when read in conjunction with the appended drawings. It is understood that potential examples of the disclosed systems and methods are not limited to those depicted.

FIG. 1 shows a simplified schematic diagram of a plasma treatment system according to one example;

FIG. 2 shows a perspective view of a chamber of the plasma treatment system of FIG. 1 according to one example, with a door of the chamber being open;

FIG. 3 shows a perspective view of a chamber of the plasma treatment system of FIG. 1 according to one example, with a door of the chamber being closed;

FIG. 4 shows a front perspective view of a workpiece support system of the plasma treatment system of FIG. 1 according to one example;

FIG. 5 shows a rear perspective view of the workpiece support system of FIG. 4 with an end cap attached thereto;

FIG. 6 shows a perspective view of an interior portion of the chamber of FIG. 2;

FIG. 7 shows a cross-sectional perspective view of a portion of the chamber of FIG. 2;

FIG. 8 shows a schematic elevation view of the workpiece support system of FIG. 4 according to one example, with upper and lower contacts of the chamber of the plasma treatment system of FIG. 1 being in contact with the upper and lower ends of the workpiece support system; and

FIG. 9 shows a simplified flow diagram of a method of operating the system of FIG. 1 according to one example.

### DETAILED DESCRIPTION

While conventional plasma processing systems have been adequate for their intended purpose, there is a need for a plasma processing system that is capable of improving the uniformity of the processing over the entire surface area of each substrate and among multiple substrates processed in any single processed lot of substrates. There is also a need for systems that can perform plasma treatment operations in shorter periods of time.

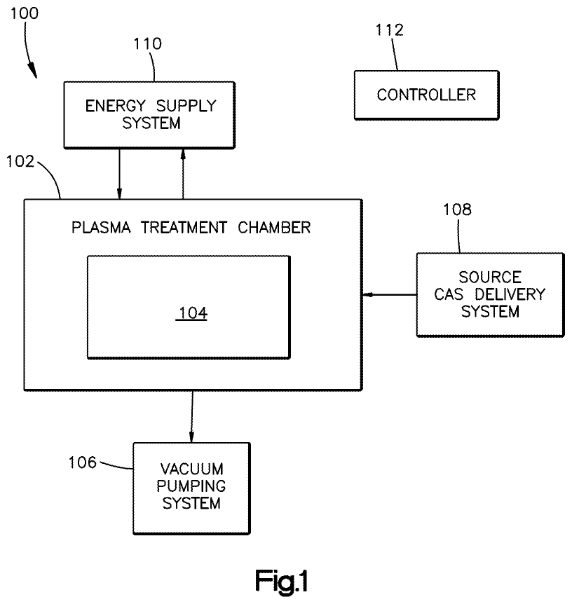

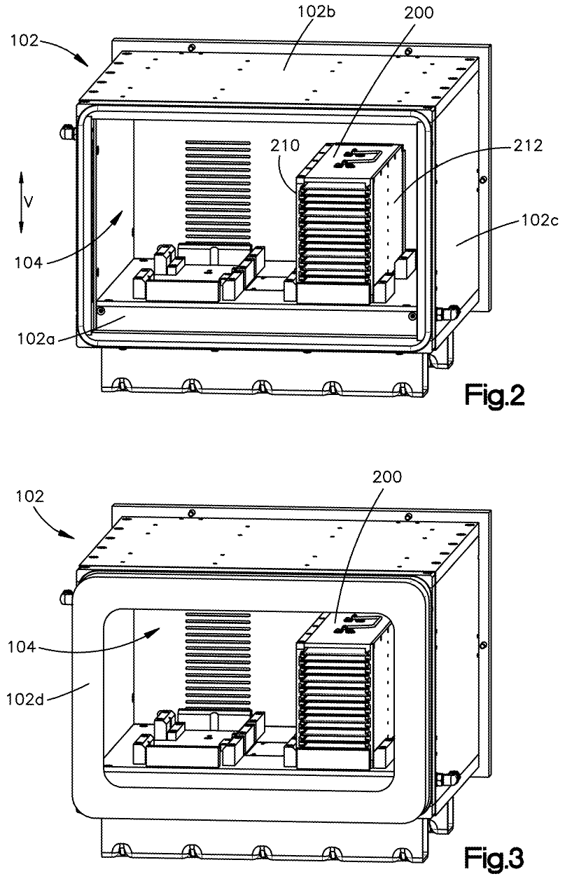

Referring to FIG. 1, a simplified schematic diagram of a plasma treatment system 100 is shown according to one example. The plasma treatment system 100 comprises a plasma treatment chamber 102 that defines a cavity 104 therein. The cavity 104 can be configured to support at least one workpiece support system 200 (e.g., as shown in FIGS. 2 to 5) therein that supports product to be plasma treated, and in some examples, can be configured to support two or more workpiece support systems 200. In some examples, the plasma treatment system 100 can comprise the workpiece support system 200, although it will be understood that the plasma treatment system 100 and the workpiece support system 200 can be distributed separately from one another. As will be described in further detail below, the workpiece support system 200 can comprise a support structure 202 and a plurality of electrodes 250a, 250b configured to be supported by the support structure 202. The workpiece support structure 202 can define a magazine that is configured to be removably received in the cavity 104. However, in other examples, the workpiece support system 200 can be fixedly attached to the plasma treatment chamber 102 inside of the cavity 104, or can be part of or integral with the plasma treatment chamber 102.

The plasma treatment system 100 comprises a vacuum pumping system 106 that is configured to at least partially evacuate the atmosphere within the cavity 104 during plasma treatment operations. For example, the vacuum pumping system 106 can be configured to draw at least a partial vacuum within the cavity 104. The plasma treatment system 100 comprises a source gas delivery system 108 that is configured to deliver a source gas to the cavity 104 during plasma treatment operations. The plasma treatment system 100 can comprise an energy supply system 110, such as a radio-frequency (RF) generator, that is configured to supply power to the workpiece support system 200 in the cavity 104. The plasma treatment system 100 can comprise a controller 112 that is configured to control operations of one or more, up to all, of the vacuum pumping system 106, source gas delivery system 108, and the energy supply system 110 to perform plasma treatment operations.

Turning to FIGS. 2 and 3, the plasma treatment chamber 102 can comprise a base 102a and a top 102b that are opposite one another along a vertical direction V. The plasma treatment chamber 102 can include at least one sidewall 102c that extends between the base 102a and the top 102b. For example, the at least one sidewall 102c can extend from the base 102a to the top 102b. The at least one sidewall 102c can define the cavity 104 between the base 102a and the top 102b. For example, the at least one sidewall 102c can extend at least partially around the cavity 104. The plasma treatment chamber 102 can comprise a chamber door 102d that can be opened to provide access to the cavity 104 inside the plasma treatment chamber 102, and closed to provide a fluid-tight seal that isolates the cavity 104 from the surrounding ambient environment. In FIG. 3, the chamber door 102d comprises a glass panel so that an interior of the chamber is visible; however, it will be understood that the chamber door need not comprise a glass pane. The chamber door 102d can positioned so as to provide access to the cavity 104 between the base 102a and the top 102b, such as through the at least one sidewall 102c. In one example, as shown, the plasma treatment chamber 102 can have a box-like shape, with the at least one sidewall 102c extending around the cavity 104. For instance, the at least one sidewall 102c can define a first side and a second side that are opposite one another along a first direction, and a backside that extends between the first and second sides. The chamber door 102d can be disposed at a front of the plasma treatment chamber 102, opposite the backside. It will be understood that, in alternative examples, the plasma treatment chamber 102 could be cylindrical or have any other suitable shape.

As shown in FIG. 6, the plasma treatment chamber 102 can comprise, for each workpiece support system 200, at least one first electrical contact 114 and at least one second electrical contact 116. The at least one first electrical contact 114 and the at least one second electrical contact 116 can be positioned in any suitable manner to electrically couple to first and second support members 210 and 212 of the workpiece support system 200. FIGS. 2, 3, and 6 show one example in which the at least one first electrical contact 114 and the at least one second electrical contact 116 are each positioned to engage a lower end of the workpiece support system 200. The at least one first electrical contact 114 engages the first support member 210 and the at least one second electrical contact 116 engages the second support member 212. In this example, the plasma treatment chamber 102 is configured to receive the workpiece support system 200 in the cavity 104 such that the workpiece support system 200 rests on the at least one first electrical contact 114 and the at least one second electrical contact 116. Further, the at least one first electrical contact 114 and the at least one second electrical contact 116 are positionally fixed within the chamber 102. In other examples, as will be described below with reference to FIG. 8, one or both of the at least one first electrical contact 114 and the at least one second electrical contact 116 can be otherwise positioned, and/or can be configured to move into and out of engagement with the workpiece support system 200.

The at least one first electrical contact 114 is configured to be electrically coupled to a first support member 210 of the workpiece support system 200, and the at least one second electrical contact 116 is configured to be electrically coupled to a second support member 212 of the workpiece support system 200. Thus, the chamber 102 is configured such that, during a plasma treatment operation, the chamber 102 applies a charge to the first electrical contact 114 is different from a charge applied to the second electrical contact 116. Thus, the first electrical contact 114 is configured to apply a first charge to the first support member 210, and the at least one second electrical contact 116 is configured apply a second charge, different from the first charge, to the second support member 212. One of the first and second electrical contacts 114 and 116 may be a powered electrical contact and the other one of the first and second electrical contacts 114 and 116 may be a grounded electrical contact. Thus, one of the first and second electrical contacts 114 and 116 can be configured to ground a respective one of the first and second support members 210 and 212. In another example, the first and second electrical contacts 114 and 116 may each be a powered electrical contact, where a power supplied by the first electrical contact 114 to the workpiece support system 200 is different from a power supplied by the second electrical contact 116 to the workpiece support system 200.

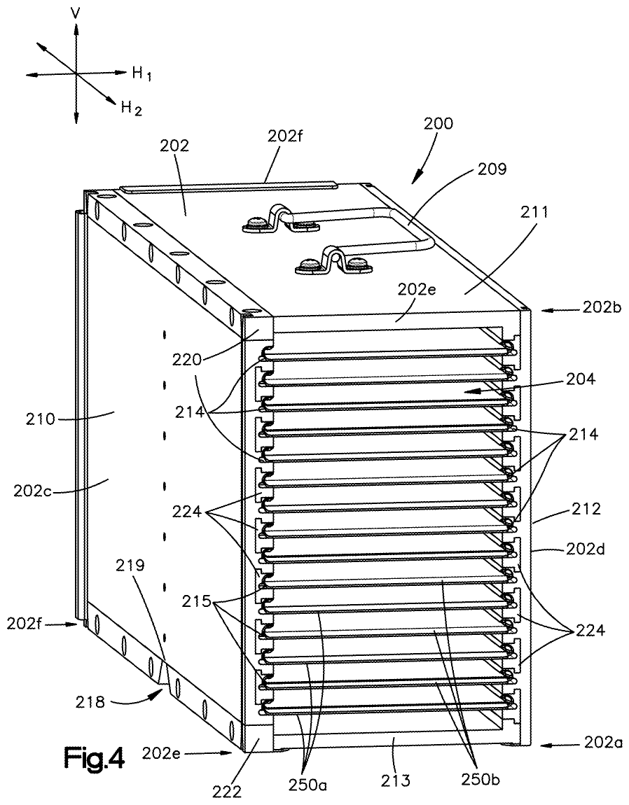

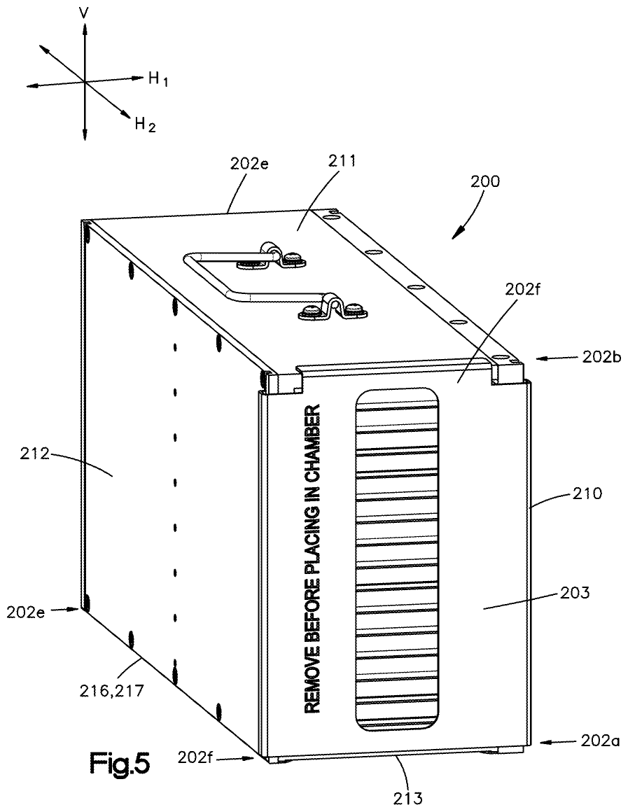

Turning now to FIGS. 4 and 5, an example of a plasma treatment workpiece support system 200 is shown. The workpiece support system 200 comprises a support structure 202 configured to be removably received in the chamber 102 of the plasma treatment system 100. The support structure 202 can be a housing that defines a cavity 204 therein. The workpiece support system 200 can comprise a plurality of electrodes 250a, 250b that are configured to be supported within the support structure 202. Thus, the support structure 202 can be configured to support the plurality of electrodes 250a, 250b in the cavity 204.

The support structure 202 has a lower end 202a and an upper end 202b that are offset from one another along the vertical direction V. The support structure 202 has a first side 202c and a second side 202d that are offset from one another along a first horizontal direction Hi. The support structure 202 can have a first end 202e and a second end 202f that are offset from one another along a second horizontal direction Hz, perpendicular to the first horizontal direction Hi. The cavity 204 can extend between the first and second ends 202e and 202f. For example, the cavity 204 can extend through one or both of the first and second ends 202e and 202f such that the cavity 204 defines an opening at one or both of the first and second ends 202e and 202f. Thus, one or both of the first and second ends 202e and 202f can be open so as to allow the source gas to enter therethrough into the cavity 204.

In some examples, as shown in FIG. 5, the support structure 202 can comprise at least one removable end cap 203, such as a pair of removable end caps. Each end cap 203 can be configured to removably attach to one of the first and second ends 202e and 202f so as to close or obstruct at least a portion of the opening at the one of the first and second ends 202e and 202f. Thus, each end cap 203 can be configured such that, when attached to one of the first and second ends 202e and 202f, the end cap 203 forms an interference with the electrodes 250a, 250b and/or product supported by the electrodes to prevent the electrodes 250a, 250b and/or product from inadvertently sliding out of the cavity 204 when transporting the support structure 202. For instance, in examples where the electrodes 250a, 250b are fixedly attached to the support structure 202 such that the electrodes 250a, 250b are not movable relative to the support structure 202, the end cap 203 can prevent the product supported by the electrodes 250a, 250b from sliding out of the cavity 204. In examples where the electrodes 250a, 250b are movably coupled to the support structure 200 such that the electrodes 250a, 250b are movable relative to the support structure 202, the end cap 203 can prevent the electrodes 250a, 250b from sliding out of the cavity 204. One or both of the end caps 203 can be removed prior to a plasma treatment operation, such as prior to the support structure 202 being received in the cavity 104.

The first and second sides 202c and 202d extend between the lower end 202a and the upper end 202b. For example, the first and second sides 202c and 202d can extend from the lower end 202a to the upper end 202b. The first and second sides 202c and 202d extend between the first end 202e and the second end 202f. For example, the first and second sides 202c and 202d can extend from the first end 202e to the second end 202f. The cavity 204 can extend between the first and second sides 202c and 202d. The first and second sides 202c and 202d can each define a plurality of slots therethrough that permit the source gas to enter therethrough into the cavity 204. However, the inventors have discovered that the slots are not necessary to obtain uniform plasma treatment across the surfaces of the product supported in the support structure 202. Consequently, each of the first and second sides 202c and 202d can be solid as it extends from the upper end to the lower end and from the front end to the rear end. Stated differently, the sides 202c and 202d can be devoid of slots or openings that extend entirely therethrough and are open to the cavity 204.

The support structure 200 has first and second support members 210 and 212 that extend between the lower end 202a and the upper end 202b. The first and second support members 210 and 212 are spaced from one another along a first horizontal direction Hi such that the cavity 204 is defined between the lower and upper ends 202a and 202b and between the first and second support members 210 and 212. In one example, the first and second sidewalls 202c and 202d can define the first and second support members 210 and 212. In other examples, the first and second support members 210 and 212 can be separate from the first and second sidewalls 202c and 202d. The support structure 202 can also have a top 211 and a bottom 213. The top 211 and bottom 213 can be spaced from one another along the vertical direction V. In one example, the support structure 202 can comprise a handle 209 that is attached to the top 211.

The first and second support members 210 and 212 are electrically isolated from one another. The first and second support members 210 and 212 are configured to support the electrodes 250a, 250b within the cavity 204 such that the electrodes 250a, 250b are offset from one another along the vertical direction V and extend between the first and second support members 210 and 212 along the first horizontal direction Hi. When supported by the first and second support members 210 and 212, a first set of the electrodes 250a are electrically coupled to the first support member 210 and electrically isolated from the second support member 212, and a second set of the electrodes 250b, different from the first set, are electrically coupled to the second support member 212 and electrically isolated from the first support member 210.

The first and second support members 210 and 212 are configured to support the electrodes 250a, 250b of the first and second sets in an alternating arrangement along the vertical direction V. For example, the first and second support members 210 and 212 can be configured to support individual ones of the electrodes 250a in the first set between different pairs of the electrodes 250b of the second set. Similarly, the first and second support members 210 and 212 can be configured to support individual ones of the electrodes 250b in the second set between different pairs of the electrodes 250a of the first set. The first and second support members 210 and 212 can be configured to removably attach to the electrodes 250a, 250b of the first and second sets, although in alternative examples, the first and second support members 210 and 212 can be fixedly attached to the electrodes 250a, 250b.

The electrodes 250a, 250b can be removably attached to the first and second support members 210 and 212. For example, each of the first and second support members 210 and 212 can define couplers 215 that are offset from one another along the vertical direction V. The couplers 215 of the first and second support members 210 and 212 can be configured to engage edges of the electrodes 250a, 250b therein so as support the electrodes 250a, 250b. In one example, each of the couplers 215 can define a recess that is configured to receive an edge of one of the electrodes 250a, 250b therein so as support the electrode 250a, 250b. For instance, the recesses 214 defined by the first support member 210 extend into the first support member 210 along the first horizontal direction Hi, away from the second support member 212, and the recesses 214 defined by the second support member 212 extend into the second support member 212 along the first horizontal direction Hi, away from the first support member 210. Each coupler 215 of the first support member 210 can be aligned with a corresponding coupler 215 of the second support 212 member along the first horizontal direction Hi. In alternative examples, the couplers 215 can be features other than recesses, such as clamps that are configured to clamp onto the electrodes 250a, 250b.

In yet still other examples, each electrode 250a, 250b can be fixedly attached to a respectively one of the first and second support members 210 and 212. For example, each electrode 250a can be fixedly attached to the second support member 212, and each electrode 250b can be fixedly attached to the first support electrode 210. Each electrode 250a, 250b can be fixed to the respective one of the first and second support members 210 and 212 by welding, soldering, or any other suitable method, or may be integral with the respective one of the first and second support members 210 and 212 so as to form a single integral unit with the respective one of the first and second support members 210 and 212.

The support structure 202 can define a first electrical contact 218 that is configured to receive the first electrical contact 114 of the chamber 102 so as to place the first electrical contact 218 of the support structure 202 and the first electrical contact 114 of the chamber 102 in electrical communication with one another. In one example, the first electrical contact 218 of the support structure 202 can be a lower electrical contact defined at the lower end 202a of the support structure 202 as shown in FIG. 4. The first electrical contact 218 of the support structure 202 can be defined by the first side 202c of the support structure 202, such as by the first support member 210.

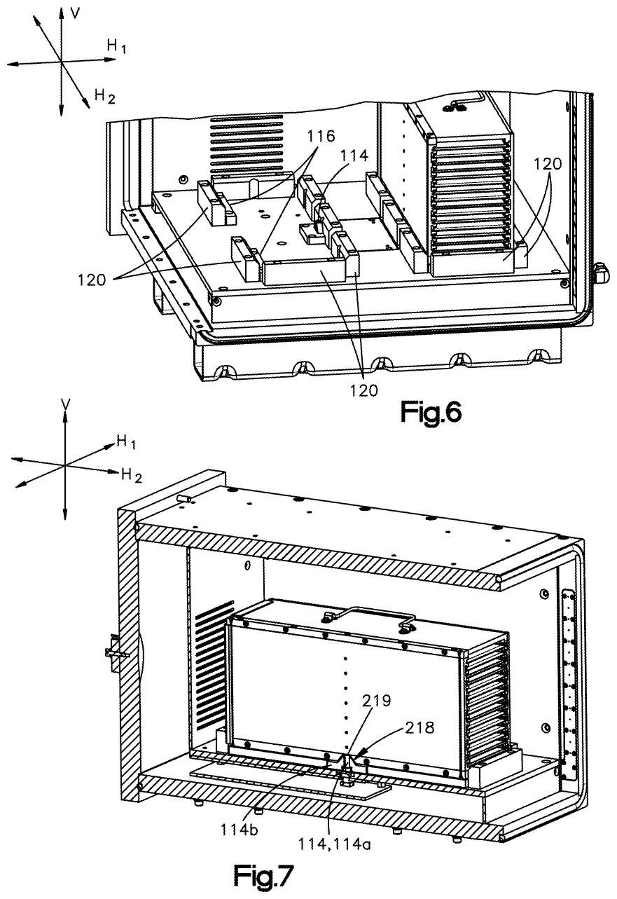

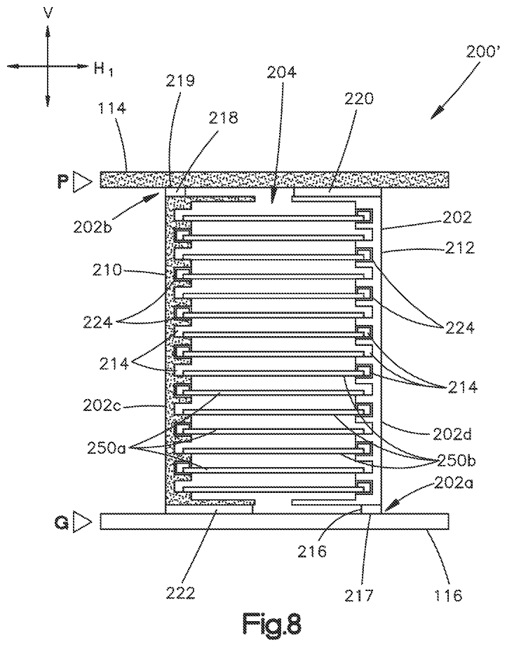

The first electrical contact 218 can be any suitable electrical contact. As one example, in FIGS. 4 and 7, the first electrical contact 218 can comprise at least one contact surface 219. The at least one contact surface 219 can, in some examples, be defined in or can define a receptacle, and the receptacle can have any suitable shape, although in other examples, such as shown in FIG. 8, the at least one contact surface 219 need not be defined in a receptacle. FIGS. 4 and 7 show one configuration of a receptacle that has a triangular shape that is configured to receive the first electrical contact 114 of the chamber 102. The first electrical contact 114 comprises a protrusion 114a that extends into the cavity 104 of the chamber 102. The protrusion can be in the shape of a pin or other can have another suitable shape. The protrusion 114a contacts the at least one contact surface 219 of the receptacle when the workpiece support structure 202 is received in the cavity 104. The electrical contact 114 can optionally comprise an alignment body 114b that is configured to engage the workpiece support structure 202, such as the receptacle, so as to align the electrical contact 114 with the contact surface 219 when the workpiece support structure 202 is received in the cavity 104 of the chamber 102. The alignment body 114b can have a shape that conforms to a shape of the receptacle of the first electrical contact 218. For example, the alignment body 114b can have at least one ramped surface that is angled relative to the vertical direction V. In one specific example, the alignment body 114b can be a triangular-shaped body having opposing ramped surfaces, although it will be understood that the alignment body 114b can have another suitable shape. The alignment body 114b can be insulative or can be electrically conducting.

The first electrical contact 218 of the workpiece support structure 202 is electrically coupled to the first support member 210 such that the first electrical contact 218 of the support structure 202 is configured to electrically couple the first electrical contact 114 of the chamber 102 with the first support member 210. The support structure 202 is configured to electrically isolate the first support member 210 from the second support member 212, and hence from the at least one second electrical contact 116 of the chamber 102 when the first electrical contact 114 of the chamber 102 is electrically coupled to the first electrical contact 218 of the support structure 202. In one example, the lower end 202a includes a lower insulator 222 that is configured to electrically isolate the first support member 210 from the second support member 212. Additionally, or alternatively, the upper end 202b includes an upper insulator 220 that is configured to electrically isolate the first support member 210 from the second support member 212.

The top 211 of the support structure 202 can be electrically coupled to one of the first and second support members 210 and 212 and electrically isolated from the other one of the first and second support members 210 and 212. In the example of FIG. 4, the top 211 is electrically coupled to the second support member 212, and electrically isolated from the first support member 210 by upper insulator 220. Similarly, the bottom 213 of the support structure 202 can be electrically coupled to one of the first and second support members 210 and 212 and electrically isolated from the other one of the first and second support members 210 and 212. In the example of FIG. 4, the bottom 213 is electrically coupled to the second support member 212, and electrically isolated from the first support member 210 by lower insulator 222. It will be understood that one or both of the top 211 and bottom 213 could alternatively be electrically isolated from the second support member 212, and electrically coupled to the first support member 210. The support structure 202 can define at least one second electrical contact 216 (labeled in FIG. 5) that is configured to receive the second electrical contact 116 of chamber 102 so as to electrically couple the second electrical contact 216 of the support structure 202 and the second electrical contact 116 of the chamber 102 with one another. The at least one second electrical contact 216 can be any suitable electrical contact. The at least one second electrical contact 216 can comprise at least one contact surface 217. The at least one contact surface 217 can, in some examples, be defined by a bottom surface of the support structure 202.

The at least one second electrical contact 216 of the support structure 202 is electrically coupled to the second support member 212 such that the second electrical contact 216 of the support structure 202 is configured to electrically couple the second electrical contact 116 of the chamber 102 with the second support member 212. The support structure 202 is configured to electrically isolate the second support member 212 from the first support member 210, and hence the first electrical contact 114 of the chamber 102, when the second electrical contact 116 of the chamber 102 is electrically coupled to the second electrical contact 216 of the support structure 202. The at least one second electrical contact 116 of the chamber 102 can have any suitable shape. In one example, each of the at least one second electrical contact 116 can be implemented as a block as shown in FIG. 6. Referring to FIG. 4, the support structure 202 can include a plurality of insulators 224 that are configured to electrically isolate the electrodes 250a of the first set from the first support 210. Similarly, the support structure 202 can include a plurality of insulators 224 that are configured to electrically isolate the electrodes 250b of the first set from the second support 212. Each insulator 224 can be disposed between a respective one of the electrodes 250a, 250b and a respective one of the first and second supports 210 and 212.

Each insulator 224 can define a coupler 215. Each coupler 215 can be configured to engage an edge of a corresponding electrodes 250a, 250b therein so as support the electrode 250a, 250b. In one example, each of the couplers 215 can define a recess that is configured to receive an edge of a corresponding one of the electrodes 250a, 250b therein so as support the electrode 250a, 250b. For instance, the recesses defined by each insulator 224 can extend into the insulator 224 along the first horizontal direction Hi. Each insulator 224 can be supported by one of the first support member 210 and the second support member 212. Each insulator 224 supported by the first support member 210 can be aligned with a corresponding coupler 215 of the second support 212 member along the first horizontal direction Hi. Each insulator 224 supported by the second support member 212 can be aligned with a corresponding coupler 215 of the first support 210 member along the first horizontal direction Hi. In alternative examples, the couplers 215 of the insulators 224 can be features other than recesses, such as clamps that are configured to clamp onto the electrodes 250a, 250b.

The first and second support members 210 and 212 are configured to support the insulator 224 in an alternating arrangement along the vertical direction. For example, every other coupler 215 of the first support member 210 can be defined by an insulator 224. Similarly, every other coupler 215 of the second support member 212 can be defined by an insulator 224. Each insulator coupler 215 supported by the first support member 210 can be aligned along the first horizontal direction Hi with a coupler 215 of the second support member 212 that is not defined by an insulator 224. Each insulator coupler 215 supported by the second support member 212 can be aligned along the first horizontal direction Hi with a coupler 215 of the first support member 210 that is not defined by an insulator 224.

Referring to FIG. 6, the chamber 102 can comprise, for each support structure 202, at least one, such as a plurality of alignment features 120. The at least one alignment feature 120 is configured to align the workpiece support 202 within the cavity 104 of the chamber 102 such that each of the at least one first electrical contact 114 of the chamber 102 is aligned with the at least one first electrical contact 218 of the workpiece support 202 and the at least one second electrical contact 216 of the chamber 102 is aligned with the at least one second electrical contact 116 of the workpiece support 202. In the example of FIG. 6, the at least one alignment feature 120 comprises at least one, such as a plurality of bodies or blocks, that conform to a footprint of the workpiece support 202. It will be understood that the at least one alignment feature 120 can be implemented in any other suitable manner. In some examples, the least one alignment feature 120 can comprise a protrusion. In some such examples, the protrusion can be received in a recess of the workpiece support 202 or on a side of the workpiece support 202. In other examples, the at least one alignment feature 120 can be a recess that receives a protrusion of the workpiece support 202. In some examples, the at least one alignment feature 120 can have a non-circular cross-section that mates with a non-circular cross-section of the workpiece support 202 so as to prevent relative rotation between the workpiece support 202 and the chamber 102.

Turning to FIG. 8, another example of a workpiece support system 200′ is shown. It will be understood that the features of FIG. 8 having like reference numerals to those discussed above may be understood with reference to the corresponding descriptions above. The workpiece support system 200′ is similar to the workpiece support system 200, with at least a few exceptions, including the positions of the first and second electrical contacts 114 and 116. In FIG. 8, the first and second electrical contacts 114 and 116 can be positioned such that one of the first and second electrical contacts 114 and 116 can be a lower electrical contact, and the other of the first and second electrical contacts 114 and 116 can be an upper electrical contact that is offset from the one of the first and second electrical contacts 114 and 116 along the vertical direction V. For instance, one of the first and second electrical contacts 114 and 116 can be configured to engage the lower end 202a of the workpiece support system 200′ and the other one of the first and second electrical contacts 114 and 116 can be configured to engage the upper end 202b of the workpiece support system 200′. In another example (not shown), the first and second electrical contacts and can be positioned such that the first and second electrical contacts are offset from one another along a first horizontal direction Hi. For example, the first and second electrical contacts can be configured to engage sides 202c and 202d, respectively, of the workpiece support system 200′. Each electrical contact 114 and 116 can be shaped as a plate or a bar or can have any other suitable shape.

One or both of the first and second electrical contacts 114 and 116 can be movable. For example, the second electrical contact 116 can be movable between a first position, wherein the second electrical contact 116 is spaced from the workpiece support system 200′ when the workpiece support system 200′ is received in the chamber 102, and a second position, wherein the second electrical contact 116 is in contact with the workpiece support system 200′ when the workpiece support system 200′ is received in the chamber 102. One or both of the first and second electrical contacts 114 and 116 can be configured to move between a first position, where a first distance is defined between the first and second electrical contacts 114 and 116, and a second position, where a second distance is defined between the first and second electrical contacts 114 and 116, the second distance being less than the first distance. The plasma treatment chamber 102 can comprise a mechanism configured to move one or both of the first and second electrical contacts 114 and 116. The mechanism can be an unpowered mechanical mechanism. The unpowered mechanical mechanism can be actuated by a lever, knob, or any other suitable actuation device. Alternatively, the mechanism can a powered mechanism that comprises any suitable powered actuator, such as an electrical actuator, a hydraulic actuator, or a pneumatic actuator.

The at least one first electrical contact 218 of the support structure 202 is configured to receive the first electrical contact 114 of the chamber 102 so as to place the first electrical contact 218 of the support structure 202 and the first electrical contact 114 of the chamber 102 in electrical communication with one another. In this example, the first electrical contact 218 of the support structure 202 is an upper electrical contact defined at the upper end 202b of the support structure 202 as shown in FIG. 8. The first electrical contact 218 can be defined by the first side 202c of the support structure 202, such as by the first support member 210 or by a contact that is attached to the support member 210.

The first electrical contact 218 can be any suitable electrical contact. The first electrical contact 218 can comprise at least one contact surface 219. In this example, unlike the examples of FIGS. 4 and 7 above, the contact surface 219 is not defined in a receptacle. The first electrical contact 218 can comprise a protrusion that extends up from the first support member 210 such that, when the first electrical contact 114 of the chamber 102 is electrically coupled to the first electrical contact 218 of the support structure 202, the first electrical contact 218 of the support structure 202 provides a clearance that spaces the first electrical contact 114 from the second support member 212.

The first electrical contact 218 of the workpiece support structure 202 is electrically coupled to the first support member 210 such that the first electrical contact 218 of the support structure 202 is configured to electrically couple the first electrical contact 114 of the chamber 102 with the first support member 210. The support structure 202 is configured to electrically isolate the first support member 210 from the second support member 212, and hence from the at least one second electrical contact 116 of the chamber 102 when the first electrical contact 114 of the chamber 102 is electrically coupled to the first electrical contact 218 of the support structure 202. In one example, the lower end 202a includes a lower insulator 222 that is configured to electrically isolate the first support member 210 from the second electrical contact 116, and hence from the second support member 212. Additionally, the upper end 202b includes an upper insulator 220 that is configured to electrically isolate the second support member 212 from the first electrical contact 114, and hence from the first support member 210.

The at least one second electrical contact 216 is configured to receive the second electrical contact 116 of chamber 102 so as to electrically couple the second electrical contact 216 of the support structure 202 and the second electrical contact 116 of the chamber 102 with one another. The at least one second electrical contact 216 can be any suitable electrical contact. The at least one second electrical contact 216 can comprise at least one contact surface 217. The at least one contact surface 217 can, in some examples, be defined by a bottom surface of the support structure 202.

The at least one second electrical contact 216 of the support structure 202 is electrically coupled to the second support member 212 such that the second electrical contact 216 of the support structure 202 is configured to electrically couple the second electrical contact 116 of the chamber 102 with the second support member 212. The support structure 202 is configured to electrically isolate the second support member 212 from the first support member 210, and hence the first electrical contact 114 of the chamber 102, when the second electrical contact 116 of the chamber 102 is electrically coupled to the second electrical contact 216 of the support structure 202. The at least one second electrical contact 116 of the chamber 102 can have any suitable shape. The lower end 202a of the support structure 202 can be configured so as to space the first support member 210 from the second electrical contact 116 of the chamber 102 when the first electrical contact 114 of the chamber 102 is electrically coupled to the first electrical contact 218 of the support structure 202.

In one example, the second electrical contact 216 of the support structure 202 can be an upper electrical contact defined at the upper end 202b of the support structure 202. In another example, the second electrical contact 216 of the support structure 202 can be defined by the first side 202c of the support structure 202, such as by the first support member 210. In one example, the upper end 202b of the support structure 202 can define an upper insulator 220 that is configured to electrically isolate the second support member 212 from the first electrical contact 114 of the chamber 102 when the first electrical contact 114 of the chamber 102 and the first electrical contact 218 of the support structure 202 are electrically coupled to one another.

With reference to FIGS. 4 and 8, the support structure 202 can comprise a mechanism (not shown) that is configured to adjust spacing between adjacent ones of the electrodes 250a, 250b. The mechanism can be configured to move at least one electrode 250a, 250b relative to an adjacent electrode 250a, 250b between a first position, wherein a first space is defined between the at least one electrode 250a, 250b and the adjacent electrode 250a, 250b, and a second position, wherein a second space is defined between the at least one electrode 250a, 250b and the adjacent electrode 250a, 250b, the second space being greater than the first space. For example, an upper electrode 250a, 250b can be moved away from an adjacent lower electrode 250a, 250b so as to increase a space therebetween. A product to be treated can then be placed on the adjacent lower electrode 250a, 250b. Increasing the spacing between the electrodes can enable the product to be placed on the adjacent lower electrode 250a, 250b without sliding the product along the adjacent lower electrode 250a, 250b. The upper electrode 250a, 250b can then be moved towards the adjacent lower electrode 250a, 250b so as to decrease the space therebetween.

In some examples, each electrode 250a, 250b can be a conductive plate that is configured to support product thereon during plasma treatment of the product. The product can be, for example (and without limitation), integrated circuits, electronic packages, printed circuit boards, leadframes, or any other suitable product to be plasma treated. In other examples, each electrode can be a conductive product that is to be plasma treated. For example, each electrode can be a conductive leadframe. Each conductive leadframe can include a plurality of patterned arrangements of electric leads, each patterned arrangement configured to be packaged in a different electrical device.

In at least some examples, product can be sufficiently treated using support structures of the present disclosure at higher pressure ranges than conventional magazines.

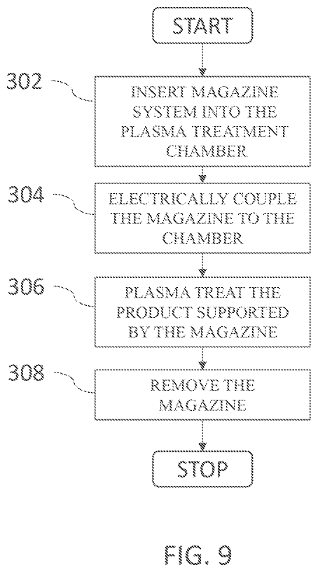

Turning now to FIG. 9, a simplified flow diagram of a method of operating the plasma treatment system of FIG. 1 is shown. The method comprises a step 302 of inserting the workpiece support system 200 into the chamber 102 of the plasma treatment system 100. The method comprises a step 304 of electrically coupling the workpiece support system 200 to the chamber 102. The electrically coupling step 304 can comprises a step of electrically coupling the second electrical contact 116 of the chamber 102 to the first support member 210 of the workpiece support system 200, and a step of electrically coupling the first electrical contact 114 of the chamber 102 to the second support member 212 of the support structure 202. In one example, as shown in FIGS. 2-7, the electrically coupling step 304 can comprise a step of receiving the lower end 202a of the support structure 202 on the first and second electrical contact 114 and 116 of the chamber 102. In another example, the electrically coupling step 304 can comprise a step of receiving the lower end 202a of the support structure 202 on the first electrical contact 114 of the chamber 102, and moving the second electrical contact 116 from a first position, wherein the second electrical contact 116 of the chamber 103 is spaced from the workpiece support system 200, to a second position, wherein the second electrical contact 116 of the chamber 102 is in contact with the workpiece support system 200. In other examples (not shown), the inserting step 302 can comprise a step of moving one or both of the first and second electrical contacts 114 and 116 to each be in contact with a respective one of the second and first sides 202d and 202c of the support structure 202. After the inserting step 302, the method can comprise a step of closing a chamber door 102d of the chamber 102 so as to provide a fluid-tight seal that isolates the cavity 104 from the surrounding ambient environment. The chamber door 102d can be closed before or after electrically coupling the workpiece support system 200 to the chamber 102.

The method comprises a step 306 of operating the plasma treatment system 100 so as to plasma treat product supported by the support structure 202. The operating step 306 can comprise a step of at least partially evacuating the atmosphere within the cavity 104 of the chamber 102. For example, the step of at least partially evacuating the cavity 104 can comprise evacuating the cavity 104 to a pressure range of between about 50 millitorrs and about 10,000 millitorrs. As another example, the step of at least partially evacuating the cavity 104 can comprise evacuating the cavity 104 to a pressure range of between about 3,000 millitorrs and about 6,000 millitorrs.

The operating step 306 can comprise a step of supplying power to one or both of the first electrical contact 114 and the second electrical contact 116 of the chamber 102. For example, the step of supplying power can comprise supplying power to one of the second and first electrical contacts 116 and 114 of the chamber 102, while the other one of the second and first electrical contacts 116 and 114 of the chamber 102 is grounded. In another example, the step of supplying power can comprise supplying a power to both the second and first electrical contacts 116 and 114 of the chamber 102, wherein the power supplied to the second electrical contact 116 of the chamber 102 is different from the power supplied to the first electrical contact 114 of the chamber 102.

The operating step 306 can comprise a step of delivering a source gas between the electrodes 250a, 250b of the workpiece support system 200 so as to plasma treat the product. The operating step 306 can comprise a step of causing the source gas to at least partially ionize to generate plasma between adjacent ones of the electrodes 250a, 250b. After the product has been plasma treated, the workpiece support system 200 can be removed from the chamber 102 in step 308.

Although not shown, the method can comprise a step of inspecting the treated product to determine whether the product has been sufficiently treated. In some examples, the product can be inspected by performing a drop contact angle test in which a contact angle of a drop of liquid on the surface of the product is measured. It has been discovered that product can be treated by plasma treatment systems of this disclosure at a higher pressure than that employed by conventional plasma treatment systems, while obtaining the same or a comparable result. For example, the pressure can be in a range of between about 50 millitorrs and about 10,000 millitorrs. In preferred embodiments, the pressure is in a range of between about 3,000 millitorrs and about 6,000 millitorrs. In fact, the inventors have discovered that operating the plasma treatment systems of the disclosure in a range of between about 3,000 millitorrs and about 6,000 millitorrs can yield consistent treatment of the product.

Because systems of the disclosure can be operated at a higher pressure, the time to evacuate the atmosphere in the cavity 104 of the plasma treatment chamber 102 can be less for each plasma treatment operation than that of conventional plasma treatment systems. As a result, systems of the disclosure can treat product quicker than that of conventional plasma treatment systems, thereby allowing more product to be treated in a shorter period of time. In other words, the time for each plasma treatment operation can be shorter than that of conventional plasma treatment systems, while yielding comparable treatment results.

Various aspects of the present disclosure can be understood in view of the following examples:

Example 1. A workpiece support structure of a plasma treatment system, the workpiece support structure comprising:

an upper end and a lower end offset from one another along a vertical direction; and

first and second support members that extend between the upper end and lower end, that are offset from one another along a first horizontal direction such that a cavity is defined between the upper and lower ends and between the first and second support members, and that are electrically isolated from one another,

wherein the first and second support members are configured to support electrodes within the cavity such that:
the electrodes are offset from one another along the vertical direction;
the electrodes extend between the first and second support members along the first horizontal direction;
a first set of the electrodes are electrically coupled to the first support member and electrically isolated from the second support member; and
a second set of the electrodes, different from the first set, are electrically coupled to the second support member and electrically isolated from the first support member.

Example 2. The workpiece support structure of Example 1, wherein the first and second support members are configured to support the electrodes of the first and second sets in an alternating arrangement along the vertical direction.

Example 3. The workpiece support structure of any of the preceding Examples, wherein the first and second support members are configured to support individual ones of the electrodes in the first set between different pairs of the electrodes of the second set.

Example 4. The workpiece support structure of any of the preceding Examples, wherein the first and second support members are configured to support individual ones of the electrodes in the second set between different pairs of the electrodes of the first set.

Example 5. The workpiece support structure of any of the preceding Examples, wherein the first and second support members are configured to removably attach to the electrodes of the first and second sets.

Example 6. The workpiece support structure of any of the preceding Examples, wherein each of the first and second support members defines couplers that are offset from one another along the vertical direction, and the couplers of the first and second support members are configured to engage edges of the electrodes therein so as support the electrodes.

Example 7. The workpiece support structure of any of the preceding Examples, wherein each of the first and second support members defines recesses that are offset from one another along the vertical direction, and the recesses of the first and second support members are configured to receive edges of the electrodes therein so as support the electrodes.

Example 8. The workpiece support structure of Example 7, wherein the recesses defined by the first support member extend into the first support member along the first horizontal direction, away from the second support member, and the recesses defined by the second support member extend into the second support member along the first horizontal direction, away from the first support member.

Example 9. The workpiece support structure of Example 8, wherein each recess of the first support member is aligned with a corresponding recess of the second support member along the first horizontal direction.

Example 10. The workpiece support structure of any of the preceding Examples, wherein the workpiece support structure defines a first electrical contact that is configured to receive a first electrical contact of chamber so as to electrically couple the first electrical contacts of the workpiece support structure and chamber with one another.

Example 11. The workpiece support structure of Example 10, wherein the first electrical contact of the workpiece support structure is electrically coupled to the first support member such that the first electrical contact of the workpiece support structure is configured to electrically couple the first electrical contact of the chamber with the first support member.

Example 12. The workpiece support structure of any of Examples 10 and 11, comprising an insulator that is configured to electrically isolate the first support member from the second electrical contact of the chamber when the first electrical contacts of the workpiece support structure and chamber are electrically coupled to one another.

Example 13. The workpiece support structure of any of the preceding Examples, wherein the workpiece support structure defines a second electrical contact that is configured to receive a second electrical contact of the chamber so as to place the second electrical contacts of the chamber and workpiece support structure in electrical communication with one another.

Example 14. The workpiece support structure of Example 13, wherein the second electrical contact of the workpiece support structure is electrically coupled to the second support member such that the second electrical contact of the workpiece support structure is configured to electrically couple the second electrical contact of the chamber with the second support member.

Example 15. The workpiece support structure of any of Examples 13 and 14, wherein the upper end of the workpiece support structure comprises an insulator that is configured to electrically isolate the second support member from the first electrical contact of the chamber when the second electrical contacts of the chamber and the workpiece support structure are electrically coupled to one another.

Example 16. The workpiece support structure of any of the preceding Examples, wherein the workpiece support structure comprises a mechanism that is configured to adjust spacing between adjacent ones of the electrodes.

Example 17. The workpiece support structure of Example 16, wherein the mechanism is configured to move at least one electrode relative to an adjacent electrode between a first position, wherein a first space is defined between the at least one electrode and the adjacent electrode, and a second position, wherein a second space is defined between the at least one electrode and the adjacent electrode, the second space being greater than the first space.

Example 18. The workpiece support structure of any of the preceding Examples, wherein the workpiece support structure has a first side and a second side that are offset from one another along the first horizontal direction, each of the first and second sides extending from the upper end to the lower end, and from a front end of the workpiece support structure to a rear end of the workpiece support structure.

Example 19. The workpiece support structure of Example 18, wherein each of the first and second sides is solid as it extends from the upper end to the lower end and from the front end to the rear end.

Example 20. The workpiece support structure of any of Examples 18 and 19, wherein each of the first and second sides is devoid of any openings that extend entirely therethrough.

Example 21. A plasma treatment system, comprising: the workpiece support structure of any of the preceding Examples; and a chamber that defines a chamber cavity therein that is configured to receive the workpiece support structure.

Example 22. The plasma treatment system of Example 21, wherein the chamber comprises a first electrical contact and a second electrical contact that are offset from one another.

Example 23. The plasma treatment system of Example 22, wherein the second electrical contact is configured to move between a first position, wherein the second electrical contact is spaced from the workpiece support structure when the plasma treatment workpiece support structure is received in the chamber, and a second position, wherein the second electrical contact is in contact with the workpiece support structure when the workpiece support structure is received in the chamber.

Example 24. The plasma treatment system of Example 22, wherein one or both of the first and second electrical contacts of the chamber is configured to move between a first position, where a first distance is defined between the first and second electrical contacts of the chamber, and a second position, where a second distance is defined between the first and second electrical contacts of the chamber, the second distance being less than the first distance.

Example 25. The plasma treatment system of any of Examples 22 to 24, wherein one of the first and second electrical contacts of the chamber is a powered electrical contact and the other one of the first and second electrical contacts of the chamber is grounded electrical contact.

Example 26. The plasma treatment system of any of Examples 22 to 25, wherein a power supplied by the first electrical contact of the chamber to the workpiece support structure is different from a power supplied by the second electrical contact of the chamber to the workpiece support structure.

Example 27. The plasma treatment system of any of Examples 21 to 26, comprising a vacuum pumping system configured to evacuate the chamber cavity to a pressure range of between about 50 millitorrs and about 10,000 millitorrs while the plasma treatment system is treating product supported in the workpiece support structure.

Example 28. The plasma treatment system of any of Examples 21 to 26, comprising a vacuum pumping system configured to evacuate the chamber cavity to a pressure range of between about 3,000 millitorrs and about 6,000 millitorrs while the plasma treatment system is treating product supported in the workpiece support structure.

Example 29. The plasma treatment system of any of Examples 21 to 28, comprising a source gas delivery system that is configured to deliver source gas between the electrodes of the electrodes.

Example 30. The plasma treatment system of Example 29, wherein the system is configured to at least partially ionize the source gas to generate plasma between adjacent ones of the electrodes.

Example 31. A workpiece support system of a plasma treatment system, the workpiece support system comprising:

a workpiece support structure configured to be removably received in a chamber of the plasma treatment system, the workpiece support structure defining a cavity therein and comprising:
an upper end and a lower end offset from one another along a vertical direction; and
first and second support members that extend between the upper end and lower end, that are offset from one another along a first horizontal direction such that the cavity is defined between the upper and lower ends and between the first and second support members, and that are electrically isolated from one another; and

electrodes configured to be supported by the first and second support members within the cavity such that:
the electrodes are offset from one another along the vertical direction;
the electrodes extend between the first and second support members along the first horizontal direction;
a first set of the electrodes are electrically coupled to the first support member and electrically isolated from the second support member; and
a second set of the electrodes, different from the first set, are electrically coupled to the second support member and electrically isolated from the first support member.

Example 32. The workpiece support system of Example 31, wherein the electrodes of the first and second sets are alternatingly arranged along the vertical direction.

Example 33. The workpiece support system of any of Examples 31 and 32, wherein individual ones of the electrodes in the first set are each disposed between a different pair of the electrodes of the second set.

Example 34. The workpiece support system of any of Examples 31 to 33, wherein individual ones of the electrodes in the second set are each disposed between a different pair of the electrodes of the first set.

Example 35. The workpiece support system of any of Examples 31 to 34, wherein the electrodes are removably attachable to the first and second support members.

Example 36. The workpiece support system of any of Examples 31 to 35, wherein the workpiece support structure defines a first electrical contact that is configured to receive a first electrical contact of the chamber so as to electrically couple the first electrical contacts of the chamber and workpiece support structure with one another.

Example 37. The workpiece support system of Example 36, wherein the first electrical contact of the workpiece support structure is electrically coupled to the second support member such that the first electrical contact of the workpiece support structure is configured to electrically couple the first electrical contact of the chamber with the second support member.

Example 38. The workpiece support system of any of Examples 36 and 37, wherein the lower end defines a lower insulator that is configured to electrically isolate the first support member from the first electrical contact of the chamber when the first electrical contacts of the chamber and workpiece support structure are electrically coupled to one another.

Example 39. The workpiece support system of any of Examples 31 to 38, wherein the workpiece support structure defines a second electrical contact that is configured to receive a second electrical contact of the chamber so as to place the second electrical contacts of the chamber and workpiece support structure in electrical communication with one another.

Example 40. The workpiece support system of Example 39, wherein the second electrical contact of the workpiece support structure is electrically coupled to the first support member such that the second electrical contact of the workpiece support structure is configured to electrically couple the second electrical contact of the chamber with the first support member.

Example 41. The workpiece support system of any of Examples 39 and 40, wherein the upper end defines an upper insulator that is configured to electrically isolate the second support member from the second electrical contact of the chamber when the second electrical contacts of the chamber and workpiece support structure are electrically coupled to one another.

Example 42. The workpiece support system of any of Examples 31 to 41, wherein each electrode is a conductive plate that is configured to support product thereon during plasma treatment of the product.

Example 43. The workpiece support system of any of Examples 31 to 41, wherein each electrode is a product that is to be plasma treated.

Example 44. The workpiece support system of Example 43, wherein each product is a conductive leadframe that includes a plurality of patterned arrangements of electric leads, each patterned arrangement configured to be packaged in a different electrical device.

Example 45. The workpiece support system of any of Examples 31 to 44, wherein the chamber comprises a mechanism that is configured to adjust spacing between adjacent ones of the electrodes.

Example 46. The workpiece support system of Example 45, wherein the mechanism is configured to move at least one electrode relative to an adjacent electrode between a first position, wherein a first space is defined between the at least one electrode and the adjacent electrode, and a second position, wherein a second space is defined between the at least one electrode and the adjacent electrode, the second space being greater than the first space.

Example 47. The workpiece support system of any of Examples 31 to 46, wherein the chamber has a first side and a second side that are offset from one another along the first horizontal direction, each of the first and second sides extending from the upper end to the lower end, and from a front end of the workpiece support structure to a rear end of the workpiece support structure.

Example 48. The workpiece support system of Example 47, wherein each of the first and second sides is solid as it extends from the upper end to the lower end, and from the front end to the rear end.

Example 49. The workpiece support system of Example 47, wherein each of the first and second sides is devoid of any openings that extend entirely therethrough.

Example 50. The workpiece support system of any Examples 31 to 49, wherein each of the first and second support members defines couplers that are offset from one another along the vertical direction, and the couplers of the first and second support members are configured to engage edges of the electrodes therein so as support the electrodes.

Example 51. The workpiece support system of any Examples 31 to 49, wherein each of the first and second support members defines a plurality of recesses are offset from one another along the vertical direction, and the recesses of the first and second pluralities are configured to receive edges of the electrodes therein so as support the electrodes.

Example 52. The workpiece support system of Example 51, wherein the recesses defined by the first support member extend into the first support member along the first horizontal direction, away from the second support, and the recesses defined by the second support member extend into the second support along the first horizontal direction, away from the first support member.

Example 53. The workpiece support system of any of Examples 51 and 52, wherein each recess of the first support member is aligned with a corresponding recess of the second support member along the first horizontal direction.

Example 54. A plasma treatment system, comprising:

the workpiece support system of any of Examples 31 to 53; and

a chamber that defines a chamber cavity therein that is configured to receive the workpiece support structure.

Example 55. The plasma treatment system of Example 54, wherein the chamber comprises a first electrical contact and a second electrical contact that are offset from one another.

Example 56. The plasma treatment system of Example 55, wherein the second electrical contact is configured to move between a first position, wherein the second electrical contact is spaced from the workpiece support structure when the workpiece support structure is received in the chamber, and a second position, wherein the second electrical contact is in contact with the workpiece support structure when the workpiece support structure is received in the chamber.

Example 57. The plasma treatment system of Example 55, wherein one or both of the first and second electrical contacts of the chamber is configured to move between a first position, where a first distance is defined between the first and second electrical contacts of the chamber, and a second position, where a second distance is defined between the first and second electrical contacts of the chamber, the second distance being less than the first distance.

Example 58. The plasma treatment system of any of Examples 55 to 57, wherein one of the first and second electrical contacts of the chamber is a powered electrical contact and the other one of the first and second electrical contacts of the chamber is grounded electrical contact.

Example 59. The plasma treatment system of any of Examples 55 to 57, wherein a power supplied by the first electrical contact of the chamber to the workpiece support structure is different from a power supplied by the second electrical contact of the chamber to the workpiece support structure.

Example 60. The plasma treatment system of any of Examples 54 to 59, comprising a vacuum pumping system configured to evacuate the chamber cavity to a pressure range of between about 50 millitorrs and about 10,000 millitorrs while the plasma treatment system is treating product supported in the workpiece support structure.

Example 61. The plasma treatment system of any of Examples 54 to 59, comprising a vacuum pumping system configured to evacuate the chamber cavity to a pressure range of between about 3,000 millitorrs and about 6,000 millitorrs while the plasma treatment system is treating product supported in the workpiece support structure.

Example 62. The plasma treatment system of any of Examples 54 to 61, comprising a source gas delivery system that is configured to deliver source gas between the electrodes of the electrodes.

Example 63. The plasma treatment system of Example 62, wherein the system is configured to at least partially ionize the source gas to generate plasma between adjacent ones of the electrodes.

Example 64. A plasma treatment system, comprising:

a chamber that defines a chamber cavity therein that is configured to receive a workpiece support structure that supports product therein that is to be plasma treated;

a first electrical contact and a second electrical contact that are offset from one another,

wherein the second electrical contact is configured to move between a first position, wherein the second electrical contact is spaced from the workpiece support structure when the workpiece support structure is received in the chamber, and a second position, wherein the second electrical contact is in contact with the workpiece support structure when the workpiece support structure is received in the chamber.

Example 65. The plasma treatment system of Example 64, wherein, in the first position, a first distance is defined between first and second electrical contacts of the chamber, and in the second position, a second distance is defined between the first and second electrical contacts of the chamber, the second distance being less than the first distance.

Example 66. The plasma treatment system of any of Examples 64 to 65, wherein one of the first and second electrical contacts of the chamber is a powered electrical contact and the other one of the first and second electrical contacts of the chamber is grounded electrical contact.

Example 67. The plasma treatment system of any of Examples 64 to 66, wherein a power supplied by the first electrical contact of the chamber to the workpiece support structure is different from a power supplied by the second electrical contact of the chamber to the workpiece support structure.

Example 68. The plasma treatment system of any of Examples 64 to 67, comprising a vacuum pumping system configured to evacuate the chamber cavity to a pressure range of between about 50 millitorrs and about 10,000 millitorrs while the plasma treatment system is treating product supported in the workpiece support structure.

Example 69. The plasma treatment system of any of Examples 64 to 67, comprising a vacuum pumping system configured to evacuate the chamber cavity to a pressure range of between about 3,000 millitorrs and about 6,000 millitorrs while the plasma treatment system is treating product supported in the workpiece support structure.

Example 70. The plasma treatment system of any of Examples 64 to 67, comprising a source gas delivery system that is configured to deliver source gas between the electrodes of the electrodes.

Example 71. The plasma treatment system of Example 70, wherein the system is configured to at least partially ionize the source gas to generate plasma between adjacent ones of the electrodes.

Example 72. A method of plasma treating product, the method comprising:

accessing a workpiece support system of any of Examples 31 to 53 in a chamber of a plasma treatment system;

electrically coupling a first electrical contact of the plasma treatment system to the first support member such that the first set of the electrodes is electrically coupled to the first support member and electrically isolated from the second support member;

electrically coupling a second electrical contact of the plasma treatment system to the second support member such that the second set of electrodes, different from the first set, is electrically coupled to the second support member and electrically isolated from the first support member; and

operating the plasma treatment system by at least partially evacuating an atmosphere within the chamber, delivering a source gas between the electrodes, and supplying power to at least one of the first and second electrical contacts of the chamber to as to establish a voltage differential between the first and second support members.

Example 73. The method of Example 72, wherein:

the step of electrically coupling the first electrical contact comprises receiving the lower end of the workpiece support structure on the first electrical contact of the chamber; and

the step of electrically coupling the second electrical contact comprises moving the second electrical contact from a first position, wherein the second electrical contact of the chamber is spaced from the workpiece support structure, to a second position, wherein the second electrical contact of the chamber is in contact with the workpiece support structure.

Example 74. The method of any of Examples 72 and 73, wherein the operating step comprises supplying power to one of the first and second electrical contacts of the chamber, while the other one of the first and second electrical contacts of the chamber is grounded.

Example 75. The method of any of Examples 72 to 73, wherein the operating step comprises supplying a power to the first and second electrical contacts of the chamber, wherein the power supplied to the first electrical contact of the chamber is different from the power supplied to the second electrical contact of the chamber.

Example 76. The method of any of Examples 72 to 75, wherein the operating step comprises evacuating the chamber to a pressure range of between about 50 millitorrs and about 10,000 millitorrs.

Example 77. The method of any of Examples 72 to 75, the operating step comprises evacuating the chamber to a pressure range of between about 3,000 millitorrs and about 6,000 millitorrs.

Example 78. The method of any of Examples 72 to 77, wherein the operating step comprises causing the source gas to at least partially ionize to generate plasma adjacent surfaces of the electrodes.

Example 79. The method of any of Examples 72 to 78, comprising a step of inserting the workpiece support structure into the chamber.

Example 80. The method of any of Examples 72 to 79, wherein each electrode is a conductive plate that is configured to support product thereon during plasma treatment of the product.

Example 81. The workpiece support system of any of Examples 72 to 79, wherein each electrode is a product that is to be plasma treated.

Example 80. The method of any of Examples 72 to 79, wherein each electrode is a conductive leadframe that includes a plurality of patterned arrangements of electric leads, each patterned arrangement configured to be packaged in a different electrical device.

It should be noted that the illustrations and descriptions of the examples shown in the figures are for exemplary purposes only, and should not be construed limiting the disclosure. One skilled in the art will appreciate that the present disclosure contemplates various examples. Additionally, it should be understood that the concepts described above with the above-described examples may be employed alone or in combination with any of the other examples described above. It should further be appreciated that the various alternative examples described above with respect to one illustrated example can apply to all examples as described herein, unless otherwise indicated.

Unless explicitly stated otherwise, each numerical value and range should be interpreted as being approximate as if the word “about,” “approximately,” or “substantially” preceded the value or range. The terms “about,” “approximately,” and “substantially” can be understood as describing a range that is within 15 percent of a specified value unless otherwise stated.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more examples or that one or more examples necessarily include these features, elements and/or steps. The terms “comprising,” “including,” “having,” and the like are synonymous and are used inclusively, in an open-ended fashion, and do not exclude additional elements, features, acts, operations, and so forth.

While certain examples have been described, these examples have been presented by way of example only and are not intended to limit the scope of the inventions disclosed herein. Thus, nothing in the foregoing description is intended to imply that any particular feature, characteristic, step, module, or block is necessary or indispensable. Indeed, the novel methods and systems described herein may be embodied in a variety of other forms; furthermore, various omissions, substitutions, and changes in the form of the methods and systems described herein may be made without departing from the spirit of the inventions disclosed herein. The accompanying claims and their equivalents are intended to cover such forms or modifications as would fall within the scope and spirit of certain of the inventions disclosed herein.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

It will be understood that reference herein to “a” or “one” to describe a feature such as a component or step does not foreclose additional features or multiples of the feature. For instance, reference to a device having or defining “one” of a feature does not preclude the device from having or defining more than one of the feature, as long as the device has or defines at least one of the feature. Similarly, reference herein to “one of” a plurality of features does not foreclose the invention from including two or more, up to all, of the features. For instance, reference to a device having or defining “one of a X and Y” does not foreclose the device from having both the X and Y.

1. A workpiece support structure of a plasma treatment system, the workpiece support structure comprising:
an upper end and a lower end offset from one another along a vertical direction; and
first and second support members that extend between the upper end and lower end, that are offset from one another along a horizontal direction such that a cavity is defined between the upper end and the lower end and between the first and second support members, wherein the first and second support members are electrically isolated from one another,
wherein the first and second support members are configured to support electrodes within the cavity such that:
the electrodes are separated from one another along the vertical direction;
the electrodes extend between the first and second support members along the horizontal direction;
a first set of the electrodes are electrically coupled to the first support member and electrically isolated from the second support member; and
a second set of the electrodes, different from the first set, are electrically coupled to the second support member and electrically isolated from the first support member.

2. The workpiece support structure of claim 1, wherein the first and second support members are configured to support the electrodes of the first set and the second set in an alternating arrangement along the vertical direction.

3. The workpiece support structure of claim 1, wherein the first and second support members are configured to support individual ones of the electrodes in the first set between different pairs of the electrodes of the second set.

4. The workpiece support structure of any of claim 1, wherein the first and second support members are configured to support individual ones of the electrodes in the second set between different pairs of the electrodes of the first set.

5. The workpiece support structure of any of claim 1, wherein each of the first and second support members defines couplers that are offset from one another along the vertical direction, and the couplers of the first and second support members are configured to engage edges of the electrodes therein so as support the electrodes.

6. The workpiece support structure of any of claim 1, wherein each of the first and second support members defines recesses that are offset from one another along the vertical direction, and the recesses of the first and second support members are configured to receive edges of the electrodes therein so as support the electrodes.

7. The workpiece support structure of any of claim 1, wherein the workpiece support structure defines a first electrical contact that is configured to engage a first electrical contact of a chamber so as to electrically couple the first electrical contacts of the workpiece support structure and the chamber with one another.

8. The workpiece support structure of claim 7, wherein the first electrical contact of the workpiece support structure is electrically coupled to the first support member such that the first electrical contact of the workpiece support structure is configured to electrically couple the first electrical contact of the chamber with the first support member.

9. The workpiece support structure of any of claim 7, comprising an insulator that is configured to electrically isolate the first support member from a second electrical contact of the chamber when the first electrical contacts of the workpiece support structure and chamber are electrically coupled to one another.

10. The workpiece support structure of any of claim 7, wherein the workpiece support structure defines a second electrical contact that is configured to receive a second electrical contact of the chamber so as to place the second electrical contacts of the chamber and workpiece support structure in electrical communication with one another.

11. The workpiece support structure of claim 10, wherein the second electrical contact of the workpiece support structure is electrically coupled to the second support member such that the second electrical contact of the workpiece support structure is configured to electrically couple the second electrical contact of the chamber with the second support member.

12. The workpiece support structure of any of claim 10, wherein the workpiece support structure comprises an insulator that is configured to electrically isolate the second support member from the first electrical contact of the chamber when the second electrical contacts of the chamber and the workpiece support structure are electrically coupled to one another.

13. The workpiece support structure of any of claim 1, wherein the workpiece support structure comprises a mechanism that is configured to adjust spacing between adjacent ones of the electrodes.

14. The workpiece support structure of any of claim 10, wherein the first and second electrical contacts of the workpiece support structure are defined at a lower end of the workpiece support structure and are configured to rest on the first and second electrical contacts of the chamber when the workpiece support structure is disposed in the chamber.

15. A workpiece support system, comprising:
the workpiece support structure of any of claim 1; and
the first and second sets of electrodes.

16. The workpiece support system of claim 15, wherein each electrode is a conductive plate that is configured to support a product thereon during plasma treatment of the product.

17. The workpiece support system of claim 15, wherein each electrode is a product that is to be plasma treated.

18. The workpiece support system of claim 17, wherein each product is a conductive leadframe that includes a plurality of patterned arrangements of electric leads, each patterned arrangement configured to be packaged in a different electrical device.

19. A method of plasma treating product, the method comprising:
accessing a workpiece support structure in a chamber of a plasma treatment system that includes first and second support members that extend along a vertical direction, are offset from one another along a horizontal direction, and are electrically isolated from one another, the first and second support members supporting a plurality of electrodes within a cavity of the workpiece support structure, the electrodes being separated from one another along the vertical direction and extending between the first and second support members along the horizontal direction;
electrically coupling a first electrical contact of the plasma treatment system to the first support member such that a first set of the electrodes is electrically coupled to the first support member and electrically isolated from the second support member;
electrically coupling a second electrical contact of the plasma treatment system to the second support member such that a second set of electrodes, different from the first set, is electrically coupled to the second support member and electrically isolated from the first support member; and
operating the plasma treatment system by at least partially evacuating an atmosphere within the chamber, delivering a source gas into the chamber, and supplying power to at least one of the first and second electrical contacts of the plasma treatment system so as to establish a voltage differential between the first and second support members that interacts with source gas to thereby generate a plasma that treats the product.

20. The method of claim 19, comprising a step of inserting the workpiece support structure into the chamber of the plasma treatment system.

21. The method of any of claim 19, wherein the step of electrically coupling the first and second electrical contacts of the chamber comprises receiving the lower end of the workpiece support structure on the first and second electrical contacts of the chamber.

22. The method of any of claim 19, wherein:
the step of electrically coupling the first electrical contact of the chamber comprises receiving the lower end of the workpiece support structure on the second electrical contact of the chamber; and
the step of electrically coupling the second electrical contact of the chamber comprises moving the second electrical contact from a first position, wherein the second electrical contact of the chamber is spaced from the workpiece support structure, to a second position, wherein the second electrical contact of the chamber is in contact with the workpiece support structure.

23. The method of any of claim 19, wherein the operating the plasma treatment system comprises evacuating the chamber to a pressure range of between about 3,000 millitorrs and about 6,000 millitorrs.

24. The method of any of claim 19, wherein each electrode is a conductive leadframe that includes a plurality of patterned arrangements of electric leads, each patterned arrangement configured to be packaged in a different electrical device.
